(19) United States
(12) Patent Application Publication
(10) Pub. No.: US 2025/0021719 A1
(43) Pub. Date: Jan. 16, 2025

(54) METHOD FOR CALCULATING THE PRESSURE LOSS IN AN INFLOW CONTROL VALVE IN A WELL IN THE PRESENCE OF FLOW CONFLUENCE

(71) Applicants: Petróleo Brasileiro S.A. – Petrobras, Rio de Janeiro (BR); Wikki Brasil Consultoria em Engenharia LTDA, Rio de Janeiro (BR)

(72) Inventors: PRISCILA MAGALHAES RIBEIRO, Rio de Janeiro (BR); MATEUS PALHARINI SCHWALBERT, Rio de Janeiro (BR); RAFAEL JAPIASSU LEITAO, Rio de Janeiro (BR); FERNANDO NASCIMENTO COELHO, Rio de Janeiro (BR); ANTONIO DE OLIVEIRA SAMEL MORAES, Rio de Janeiro (BR); EMILIO JOSE ROCHA COUTINHO, Rio de Janeiro (BR); LEONARDO OSORIO PELISOLI, Rio de Janeiro (BR); JOVANI LUIZ FAVERO, Rio de Janeiro (BR); RODRIGO ARAUJO CARDOSO DIAS, Niterói (BR)

(21) Appl. No.: 18/752,101

(22) Filed: Jun. 24, 2024

(30) Foreign Application Priority Data
Jul. 11, 2023 (BR) BR 1020230138608

(51) Int. Cl. G06F 30/18

(52) U.S. Cl. CPC G06F 30/18

(57) ABSTRACT

The invention described herein proposes that the study of pressure loss in an intelligent completion valve (ICV) is carried out considering both different annular flows and the existence of an axial flow coming from an upstream zone. To study pressure losses in ICVs in detail, the CFD-based methodology (Computational Fluid Dynamics) was adopted, where the geometry of a valve can be well represented by a detailed numerical simulation mesh, which allows high precision results. The invention described herein proves that when more than one completed interval produces simultaneously, a phenomenon that we call fluid confluence occurs, and this is responsible for an additional pressure loss. When there is a confluence of fluids, the pressure loss in the valve depends on both the flow coming from the annulus and the flow coming from upstream zones. The present invention proposes that a detailed pressure loss study be carried out for each valve, considering different flows of annular and column, with fluid properties consistent with the reservoir fluid. Numerical experiments are capable of providing pressure loss values that can be reproduced later. The present invention also provides a quadratic mathematical model that can be adjusted with the data obtained in the pressure loss studies detailed above.

The present invention falls within the field of petroleum engineering. More specifically, the present invention is related to techniques for characterizing pressure loss in intelligent completion valves under the effect of flow confluence.

### BACKGROUND OF THE INVENTION

The knowledge of the flow contribution of each interval in a well with selective completion is crucial information for the correct characterization and management of the reservoir. These contributions may vary over time, both due to changes in the conditions of the well itself—driving of bottom valves, fouling, and other factors—and due to interference from other wells in the reservoir. As downhole flow meters are not available, different methodologies needed to be developed trying to provide the flow apportionment between the intervals.

In the case of wells equipped with smart completion, which have multiple pressure sensors at different points inside the well, efforts are normally focused on measuring and using the pressure loss in the different elements of the column to infer the flow apportionment. Calibrated pressure loss coefficients (Cv) are used to determine the flow contribution of each interval (Oliveira, E. A. P. de; Almeida, B. R. de; Martini, D. B.; Toledo, L. N. Medição Virtual da Vazão de um Poço ou Intervalo Produtor Através de Dados de Pressão de Fundo de Poço. Anais da Rio Oil & Gas Expo and Conference 2012. IBP. Rio de Janeiro. 2012), since there are pressure recorders in the annulus and column, providing the total pressure differential between the measurement point in the annulus and the pressure recorder in the production column. The loss of load between registers includes, in addition to the tubular elements, the passage of fluid through the bottom valves.

In the conventional technique, Cv is commonly treated as constant, having a characteristic value for each position in the case of a multiposition valve, regardless of the flow rate passing through the valve. Another important point to highlight is that the experiment to determine this coefficient only considers the flow rate that exits from the annulus and enters the column through the valve orifices: no flow existing inside the column from an upstream production zone is considered.

Field observations have shown that the application of the constant pressure loss coefficient to determine the flow rate per interval, even calibrated through selective tests, does not present satisfactory results when the well present three or more selectively completed zones. The deviation is even more significant in high-flow wells, making it clear that there is an additional pressure loss that the prior art approach is unable to reproduce. Knowledge of this limitation highlights the need for a well-established methodology that provides consistent results to estimate the contribution of each interval when different zones produce jointly.

### STATE OF THE ART

Publication WO2021046221A1, entitled “Systems and methods for operating downhole inflow control valves to provide sufficient pump intake pressure”, refers to techniques for operating a hydrocarbon well having inflow control valves (ICVs) and an electrical submersible pump (ESP) disposed in a wellbore of the well. Baseline production data is acquired for a relatively small subset of the possible operating configurations of ICVs in the well, the baseline data is assessed to model fluid pressure gradients in the wellbore, and the modeled fluid pressure gradients are used to estimate an ESP intake pressure for one or more configurations of the ICVs, and the ICVs are controlled to operate in accordance with an ICV configuration associated with an estimated ESP intake pressure that is within an operating intake pressure range for the ESP. The technology revealed in the publication referenced above provides, among other things, a hydrocarbon well system including: ICVs disposed in a wellbore of a hydrocarbon well; an ESP disposed in the wellbore of the hydrocarbon well; and a well control system configured to perforin the following operations: conducting isolated production flow testing, comprising, for each inflow' control valve (ICV) of the hydrocarbon well: identifying a set of isolated test states for the ICV, the set of isolated test states comprising at least two partially-opened valve states and a fully-opened valve state; closing the other ICVs of the hydrocarbon well to inhibit production flow through the other ICVs; and for each isolated test state of the set of isolated test states: operating, with the other ICVs closed, the ICV in the isolated test state to enable isolated production fluid flow through the ICV and the wellbore; and determining an intake pressure for the isolated test state, the intake pressure for the isolated test state comprising a fluid pressure of the isolated production fluid flow at an intake of the ESP while the ICV is operated in the isolated test state with the other ICVs closed; conducting comingled production flow testing. See, for example, paragraphs 10-13, 35-47.

Publication WO2020232218A1, entitled “Automated production optimization technique for smart well completions using real-time nodal analysis”, discloses systems and methods that include a method for optimizing smart well completions using real-time nodal analysis including recommending changes to downhole settings. Real-time well rates and flowing downhole pressure data at various choke settings for multiple flow conditions are collected for each lateral of a multilateral well. Recommended optimizing changes to downhole inflow control valve (ICV) settings for surface and subsurface ICVs are determined based on the real-time well rates and the flowing downhole pressure data. The optimizing changes are designed to optimize production in the multilateral well. The recommended optimizing changes to the downhole ICV settings for the surface and subsurface ICVs in the laterals are provided for presentation to a user in a user interface of a multilateral well optimizing system. A user selection of one or more of the recommended optimizing changes is received. The recommended optimizing changes selected by the user are implemented.

Application U.S. Pat. No. 20,222,59972A1, entitled “Systems and methods to determine the productivity index of individual laterals under commingled flow”, discloses systems and methods for determining the productivity indices for individual laterals of a completed multilateral well under commingled flow comprising a productivity index generator, zonal inflow control valves (ICVs), and a pressure downhole monitoring system (PDHMS). The completed multilateral well comprises a mother bore and a plurality of laterals extending from the mother bore in corresponding well zones of the mother bore. Each zonal ICV is configured to close for a shut-in period and open for an open period. PDHMS is configured to generate real time pressure measurements for each well zone of the mother bore. The productivity index generator is communicatively coupled to the zonal ICVs and the PDHMS and is operable to determine a productivity index for individual laterals under commingled flow based on (i) the productivity index ratio of individual laterals under non-commingled flow and (ii) the global well productivity index under commingled flow.

Therefore, the technique lacks a solution that more accurately characterizes the pressure losses involved in smart completion wells in multiple zones for subsequent inference of the flow rate contribution of each zone individually.

### SUMMARY OF THE INVENTION

The invention described herein proposes that the pressure loss study in an intelligent completion valve (ICV) is carried out considering both different annular flows and the existence of an axial flow coming from an upstream zone. To study pressure losses in ICVs in detail, the CFD-based methodology (Computational Fluid Dynamics) was adopted, where the geometry of a valve can be well represented by a detailed numerical simulation mesh, which allows high precision results. The invention described herein proves that when more than one completed interval produces simultaneously, a phenomenon occurs that we call fluid confluence, and this is responsible for an additional pressure loss. Fluid confluence occurs when the flow that exits the annulus, passing through the valve hole, and finds itself inside the column with the flow coming from an upstream zone. This effect causes a change in the behavior of the pressure losses and means that a pressure loss coefficient for a given valve opening is no longer constant. When there is a confluence of fluids, the pressure loss in the valve depends on both the flow coming from the annulus and the flow coming from upstream zones.

The difference with this revelation is precisely knowing the behavior of Cv in the presence of a pre-existing flow rate in the column—something not considered relevant in the state of the art, not even by equipment manufacturers. The present invention proposes that a detailed pressure loss study be carried out for each valve, considering different flows of annular and column, with fluid properties consistent with the reservoir fluid. Numerical experiments or laboratory tests are capable of providing pressure loss values that can later be reproduced by an equation in the following format:

$$Δ p = ρ ( {β}_{0} {Q}_{an}^{2} + {β}_{1} {Q}_{an} {Q}_{col} + {β}_{2} {Q}_{col}^{2} + {β}_{3} {Q}_{an} + {β}_{4} {Q}_{col} ) \qquad ( 1 )$$

Where Δp is the pressure loss (pressure variation), ρ represents the density of the flowing fluid, Qan the flow rate coming from the annulus that passes through the valve hole, Qcol is the axial flow coming from an upstream zone, and β0, β1, β2, β3, β4 are the model parameters that will be adjusted based on the data obtained.

The adjustment of the coefficients (parameters) of equation 1 is obtained from pressure loss data considering different flow combinations in the column and annulus. This data can come from numerical simulation or laboratory tests. Multivariate regression is used defining as a cost function the error between the point predicted by the adjustment and the simulation data or the data measured in the case of a bench laboratory experiment.

### BRIEF DESCRIPTION OF THE DRAWINGS

The patent or application file contains at least one drawing executed in color. Copies of this patent or patent application publication with color drawing(s) will be provided by the Office upon request and payment of the necessary fee.

The present invention will now be described below with reference to the typical embodiments thereof and also with reference to the attached drawings, in which:

FIG. 1 is a representation of a fluid inlet from the annulus to the column passing through a valve, according to the prior art;

FIG. 2 is a schematic representation with pressure measurement points according to the prior art;

FIG. 3 is a schematic representation of the completion of a three-zone well in accordance with the present invention;

FIG. 4 is a representation of a fluid inlet from an annulus into a column passing through the hole of a valve in the presence of a pre-existing flow in the column, in accordance with the present invention;

FIG. 5A is a representation of a smart completion valve in accordance with the present invention;

FIG. 5B is a representation of the fluid passage details through the computational mesh according to the present invention;

FIG. 6 is a representation of a section of a valve showing the flow lines during flow confluence, in accordance with the present invention;

FIG. 7 is a representation of a flowchart describing the general methodology of the present invention;

FIG. 8 is a representation of a numerical simulation mesh in accordance with the present invention;

FIG. 9 is a representation of flow lines during a confluence of flows, in accordance with the present invention;

FIG. 10 is a representation of a graph relating the data obtained in FIG. 9 converted to Cv, in accordance with the present invention; and

FIG. 11 is a representation of a three-dimensional graph of a pressure loss surface using the data obtained in FIGS. 9 and 10, in accordance with the present invention.

### DETAILED DESCRIPTION OF THE INVENTION

Specific embodiments of this disclosure are described below. In an effort to provide a concise description of these embodiments, all features of an actual implementation may not be described in the specification. It should be appreciated that in the development of any actual implementation, as in any engineering project or design, numerous implementation-specific decisions must be made to achieve developers' specific goals, such as compliance with system-and business-related constraints, which can vary from one implementation to another. Furthermore, it should be appreciated that such a development effort may be complex and time-consuming, but would nevertheless be a routine design and manufacturing undertaking for those of ordinary skill having the benefit of this disclosure.

The study that culminated in the invention presented herein was motivated by the need to understand why the mechanistic theory applied to the apportionment of flow rate between zones does not provide good results when applied in the field for completion in three or more zones (and even in two zones a depend on the positioning of the column pressure sensor and the flow rate experienced by the well) and, in this process, seek alternatives for estimating bottom flows.

The hypothesis that the confluence of flows would be responsible for the unsatisfactory results of the mechanistic methodology described above was tested via CFD modeling (computational fluid dynamics), which allowed the detailed characterization of the pressure losses in the main ICV models. The difference in the present disclosure is precisely to verify the behavior of the pressure loss coefficient of a valve in the face of a pre-existing flow rate in the column-something not considered relevant in the state of the art, not even by the equipment manufacturers.

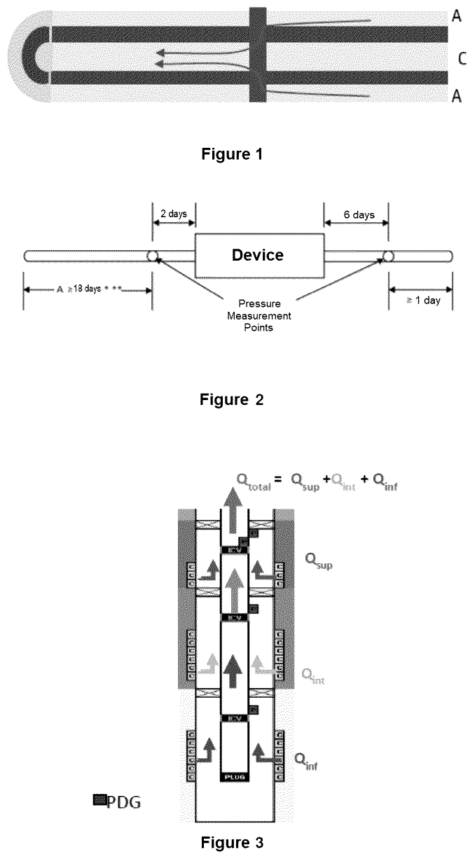

The standard approach is to calculate a constant pressure loss coefficient, for example, through laboratory experiments as represented in FIG. 1, which illustrates a fluid inlet from an annulus (A) to a column (C) passing through a valve with flow rate. Another approach is through selective field tests (production of each zone individually to calibrate an equivalent Cv). This coefficient, together with the pressure differences between registers at different positions in the downhole, is used to determine the flow rate of each interval individually.

Cv coefficients are measured by valve manufacturers following the guidance of the ANSI/ISA-75.02.01-2008 standard for experiments and pressure measurement points, as seen in the example in FIG. 2, which is a schematic with measurement points pressure according to the aforementioned standard.

Therefore, Cv is calculated using equation 2 below:

$${C}_{v} = \frac{Q}{{N}_{1}} \sqrt{\frac{\frac{{ρ}_{1}}{{ρ}_{0}}}{Δ P}} \qquad ( 2 )$$

where Q is the flow rate through the valve, N₁ is a unit conversion constant, ρ₁ is the specific mass of the fluid in the flow, ρ₀ is the specific mass of water and ΔP is the pressure difference measured between the points determined by the aforementioned standard.

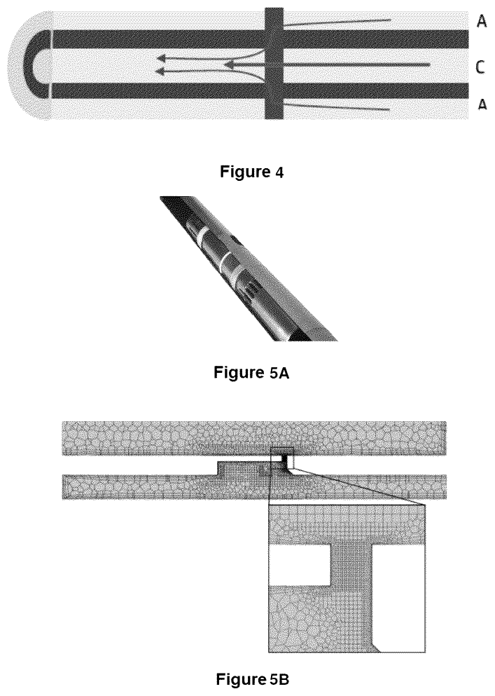

The methodology used in this work consists of carrying out CFD simulations of the flow in a given downhole valve considering the characteristic fluid and multiple flow rate combinations, in order to reproduce the confluence between the annular flow of that zone and the flows of upstream zones. An example of this type of scenario is seen in FIG. 4, which is a representation of a fluid inlet from an annulus A into a column C passing through the hole of a valve at a flow rate Qₐₙ in the presence of a pre-existing flow in the column which flow rate is represented by Q_{col}.

For this purpose, several simulations are carried out, varying several parameters, such as: equipment; opening the equipment (in the case of multiposition valves); fluid properties; and operating scenario (production or injection).

Briefly, the methodology for generating simulated data consists of, based on technical drawings and/or photos of the valves, building 3D models using free software Salome, for example. With the 3D model ready, the next step is to build a computational mesh for CFD simulations. These meshes can be generated using an application called cfMesh, for example, present in the free framework of OpenFOAM. An alternative is the tool Fluent Meshing. To generate the volumetric mesh, the discretization of the imported surface mesh is respected, using polyhedral elements and applying the boundary layers to the walls. Thus, a better control over the sizes of the mesh cells in each region is possible. With the generated meshes, simulations can be performed. For this, free software OpenFoam (OPENCFD, 2022c) can be used. The last step consists of post-processing the data and processing all the data generated.

Although the use of the tools mentioned above requires in-depth knowledge of them and related theoretical concepts, these are, however, common and ordinary knowledge for those skilled in the art. Therefore, the use of tools and interpretation of the data obtained are points that are beyond the scope of this description and will not be addressed herein.

The simulations are designed by defining the pressure measurement points according to the ANSI/ISA-75.02.01-2008 standard guidelines. In the end, the objective is to generate curves that correlate the pressure drops measured with the parameters mentioned above, considering the effect of confluence on the flow.

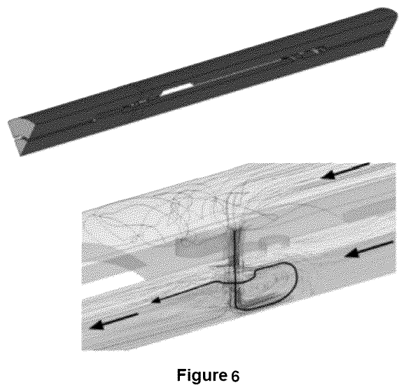

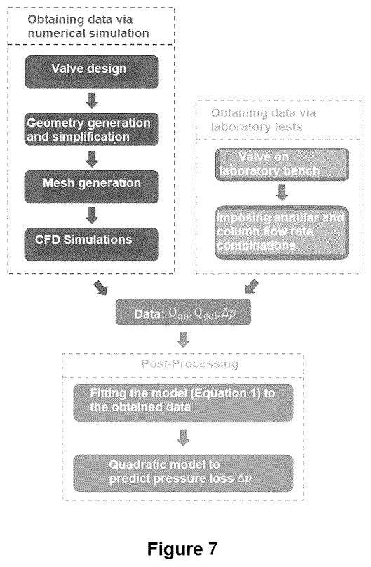

The computational meshes generated from smart completion valve schematics like the one in FIG. 5A are composed of more than two million cells, as seen in FIG. 5B. This allows simulations with great detail and precision (FIG. 6). The data set generated by around five thousand of these simulations was then used to adjust the parameters of equation 1, which was obtained from the energy balance. FIG. 7 presents the methodology described herein in the form of a flowchart. It is important to note that this flowchart presents two ways of obtaining data to adjust the parameters of the equation, numerical simulation and laboratory tests. It should also be noted that equation 1 must be adjusted with numerical simulation data or data from laboratory experiments.

Next, the result of applying the proposed methodology to verify the influence of flow confluence on the pressure losses experienced by an intelligent completion valve will be presented.

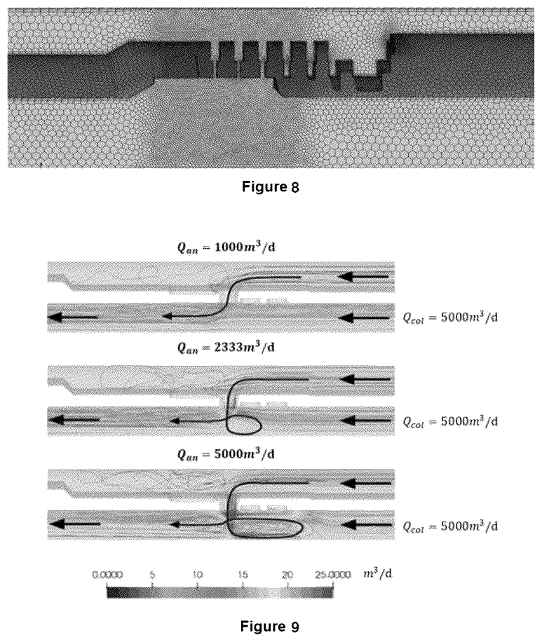

FIG. 8 shows the detail of the extremely refined simulation mesh, especially through the valve hole.

Table A below presents the results of pressure loss simulations in table form for different annular flow rate combinations (Qₐₙ) and column flow rate (Q_{col}) for a reference valve in an exemplary position 7. The pattern of laboratory experiments prior to this invention is represented by the first row of this table, i.e., null column flow rate.

FIG. 9 shows the flow lines for three different flow rate combinations, showing the existence of stronger recirculation as the flow rate increases.

TABLE A
Position 7

| | | Annular Flow [m³/day] | | | |
|---|---|---|---|---|---|
| Δp 1-3 [kgf/cm²] | | 1000 | 2333 | 3666 | 5000 |
| Column Flow | 0 (manufacturer's Δp) | 0.040 | 0.207 | 0.503 | 0.926 |
| [m³/day] | 1000 | 0.089 | 0.308 | 0.657 | 1.136 |
| | 2333 | 0.174 | 0.461 | 0.874 | 1.415 |
| | 3666 | 0.278 | 0.639 | 1.118 | 1.724 |
| | 5000 | 0.612 | 1.163 | 1.824 | 2.601 |

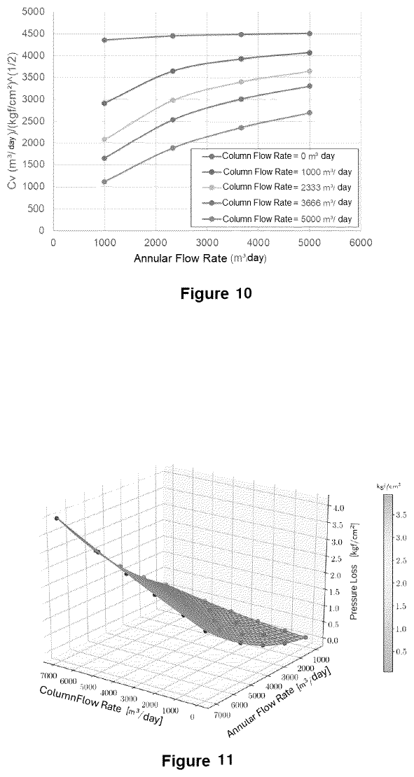

FIG. 10 is a graph relating the results obtained converted to Cv using Equation 2. It is possible to identify that the pressure loss coefficient of the valve is constant (independent of the flow rate passing through the valve hole) only when the column flow rate (coming from an upstream zone) is null. As we consider the confluence of flows, this coefficient starts to vary with the two flow rates in question. With this, it is possible to construct a pressure loss surface as illustrated in FIG. 11 from the simulated results listed in Table B, the color scale represents the pressure loss in the unit kgf/cm².

TABLE B
Example of pressure loss for different combinations of annular flow rate
and column for a reference valve in the maximum opening position.

| | | Annular Flow Rate (m³/d) | | | | |
|---|---|---|---|---|---|---|
| | | 1000 | 2333 | 3666 | 5000 | 7000 |
| Flow | 0 | a: 0.040 | a: 0.207 | a: 0.503 | a: 0.926 | a: 1.799 |
| Rate | | b: 0.040 +/− 0.0002 | b: 0.206 +/− 0.0006 | b: 0.502 +/− 0.0013 | b: 0.927 +/− 0.0023 | b: 1.808 +/− 0.0043 |
| Column | | c: −0.002 | c: 0.005 | c: 0.002 | c: −0.001 | c: −0.005 |
| (m³/d) | 1000 | a: 0.089 | a: 0.308 | a: 0.657 | a: 1.136 | a: 2.094 |
| | | b: 0.089 +/− 0.0007 | b: 0.307 +/− 0.0010 | b: 0.654 +/− 0.0017 | b: 1.131 +/− 0.0027 | b: 2.089 +/− 0.0047 |
| | | c: −0.007 | c: 0.003 | c: 0.005 | c: 0.004 | c: 0.003 |
| | 2333 | a: 0.174 | a: 0.461 | a: 0.874 | a: 1.415 | a: 2.471 |
| | | b: 0.173 +/− 0.0017 | b: 0.460 +/− 0.0022 | b: 0.875 +/− 0.0030 | b: 1.421 +/− 0.0040 | b: 2.482 +/− 0.0062 |
| | | c: 0.005 | c: 0.004 | c: −0.001 | c: −0.004 | c: −0.004 |
| | 3666 | a: 0.278 | a: 0.639 | a: 1.118 | a: 1.724 | a: 2.872 |
| | | b: 0.277 +/− 0.0030 | b: 0.632 +/− 0.0036 | b: 1.117 +/− 0.0046 | b: 1.731 +/− 0.0059 | b: 2.894 +/− 0.0083 |
| | | c: 0.002 | c: 0.010 | c: 0.001 | c: −0.004 | c: −0.008 |
| | 5000 | a: 0.398 | a: 0.836 | a: 1.386 | a: 2.057 | a: 3.300 |
| | | b: 0.402 +/− 0.0048 | b: 0.825 +/− 0.0055 | b: 1.378 +/− 0.0067 | b: 2.061 +/− 0.0081 | b: 3.328 +/− 0.0108 |
| | | c: −0.009 | c: 0.013 | c: 0.006 | c: −0.002 | c: −0.008 |
| | 7000 | a: 0.612 | a: 1.163 | a: 1.824 | a: 2.601 | a: 3.990 |
| | | b: 0.627 +/− 0.0084 | b: 1.153 +/− 0.0092 | b: 1.809 +/− 0.0105 | b: 2.595 +/− 0.0122 | b: 4.016 +/− 0.0154 |
| | | c: −0.025 | c: 0.008 | c: 0.008 | c: 0.002 | c: −0.007 |

Where:
a: Simulated value; b: Adjusted value; and c: Discrepancy in values.

Proving the effect of flow confluence—showing that the pressure loss coefficient cannot be constant in the presence of upstream flow rate—is the main contribution of this revelation. To characterize the pressure losses in a smart completion valve in multiple zones, it is necessary to consider both the annular flow rate and the column flow rate.

The present invention proposes an appropriate methodology to describe the behavior of pressure losses in intelligent completion valves in wells with multiple zones, proving and quantifying the effect of confluence. This knowledge, and the correlation generated, allows a better estimate of the flow rate contribution per interval. Knowing the contribution of each interval improves reservoir characterization and management, optimizing the exploitation strategy and increasing the field recovery factor.

The results confirmed and quantified the effect of fluid confluence when more than one zone produces at the same time, which consists of a paradigm shift regarding flow in intelligent completions. Equations were generated for pressure loss modeling considering the column flow rate and annular flow rate, which can be used for more reliable modeling of pressure losses in wells with multiple intelligent completion zones. The methodology needs to be replicated for each valve model to be considered, generating additional pressure loss curves.

As possible impacts, a better estimate of the flow contribution per interval is expected; improvement in the adjustment of reservoir models; the best selection of equipment for completion; in addition to being able to influence the design of the next generations of ICVs.

Although the aspects of the present disclosure may be susceptible to various modifications and alternative forms, specific embodiments have been shown by way of example in the drawings and have been described in detail herein. But it should be understood that the invention is not intended to be limited to the particular forms disclosed. Instead, the invention must cover all modifications, equivalents and alternatives that fall within the scope of the invention as defined by the following appended claims.

1. A method for calculating pressure loss in an inflow control valve in a well in the presence of flow confluence, comprising the steps of:
identifying a characteristic geometry of the inflow control valve;
generating a simulation mesh representative of a completion well;
performing multiple flow simulations using CFD (Computational Fluid Dynamics) considering multiple and different combinations of column flow rate and annular flow rate;
applying a quadratic model to predict pressure loss; and
adjusting the coefficients of the quadratic model to reproduce data from CFD simulations using multivariate regression.

2. The method according to claim 1, wherein the quadratic model is represented by the following equation:
$$Δ p = ρ ( {β}_{0} {Q}_{an}^{2} + {β}_{1} {Q}_{an} {Q}_{col} + {β}_{2} {Q}_{col}^{2} + {β}_{3} {Q}_{an} + {β}_{4} {Q}_{col} ) . \qquad ( 1 )$$

3. A method for calculating pressure loss in an inflow control valve in a completion well in the presence of flow confluence, comprising the steps of:
identifying the characteristic geometry of the inflow control valve;
carrying out multiple experimental tests to obtain pressure loss data considering multiple and different combinations of column flow rate and annular flow rate;
applying a quadratic model to predict pressure loss; and
adjust coefficients of the quadratic model to reproduce data from experimental tests using multivariate regression.

4. The method, according to claim 3, wherein the quadratic model is represented by the following equation:
$$Δ p = ρ ( {β}_{0} {Q}_{an}^{2} + {β}_{1} {Q}_{an} {Q}_{col} + {β}_{2} {Q}_{col}^{2} + {β}_{3} {Q}_{an} + {β}_{4} {Q}_{col} ) . \qquad ( 1 )$$

5. A method for calculating pressure loss in an inflow control valve in a completion well in the presence of flow confluence, comprising the steps of:
identifying the characteristic geometry of the inflow control valve;
generating a simulation mesh representative of the completion well;
obtaining pressure loss data considering multiple and different combinations of column flow rate and annular flow rate;
applying a quadratic model to predict pressure loss; and
adjusting coefficients of the quadratic model to reproduce the pressure loss obtained using multivariate regression.

6. The method according to claim 5, wherein the quadratic model is represented by the following equation:
$$Δ p = ρ ( {β}_{0} {Q}_{an}^{2} + {β}_{1} {Q}_{an} {Q}_{col} + {β}_{2} {Q}_{col}^{2} + {β}_{3} {Q}_{an} + {β}_{4} {Q}_{col} ) . \qquad ( 1 )$$

7. The method according to claim 5, wherein the obtaining pressure loss data includes performing multiple flow simulations using CFD (Computational Fluid Dynamics).

8. The method according to claim 5, wherein the obtaining pressure loss data includes carrying out multiple experimental tests.
